(19) United States
(12) Patent Application Publication
(10) Pub. No.: US 2026/0297726 A1
(43) Pub. Date: Oct. 1, 2026

(54) FILM DEPOSITION APPARATUS

(71) Applicant: Tokyo Electron Limited, Tokyo (JP)

(72) Inventors: Syuji NOZAWA, Yamanashi (JP); Tatsuya YAMAGUCHI, Yamanashi (JP)

(73) Assignee: Tokyo Electron Limited, Tokyo (JP)

(21) Appl. No.: 19/676,871

(22) Filed: May 14, 2026

Related U.S. Application Data
(63) Continuation of application No. PCT/JP2024/041054, filed on Nov. 20, 2024.

(30) Foreign Application Priority Data
Dec. 4, 2023 (JP) 2023-204688

(51) Int. Cl. C23C 14/54; C23C 14/12; C23C 14/50

(52) U.S. Cl. CPC C23C 14/541; C23C 14/12; C23C 14/50

(57) ABSTRACT

A film deposition apparatus includes a processing container, a stage, a heat-insulating member, a gas supply, a first heater, and a second heater. The heat-insulating member includes a plurality of penetration holes, and is located on or above the stage to cover the substrate placed on the stage. The gas supply supplies gas of a first monomer and gas of a second monomer into the processing container to form an organic film of a polymer on the substrate by a polymerization reaction between the first monomer and the second monomer. The first heater heats a side wall of the processing container to a first temperature. The second heater heats the stage to a second temperature. In a case where the organic film of the polymer is formed on the substrate, the heat-insulating member is in contact with the stage, and is not in contact with the processing container.

### CROSS-REFERENCE TO RELATED APPLICATIONS

This application is a continuation of International Application No. PCT/JP2024/041054, filed on Nov. 20, 2024 which claims the benefit of priority of the prior Japanese Patent Application No. 2023-204688, filed on Dec. 4, 2023, the entire contents of each are incorporated herein by reference.

### FIELD

Exemplary embodiments disclosed herein relate to a film deposition apparatus.

### BACKGROUND

For example, Japanese Laid-open Patent Publication No. 2018-181955 discloses “a film deposition apparatus for forming a polymer film on a substrate to be processed by vapor deposition polymerization, which includes a stage, a stage heater, a top plate heater, and a control device. The stage is provided in a processing container that accommodates therein the substrate to be processed, and the substrate to be processed is placed on the stage. The stage heater is provided in the stage to heat the substrate to be processed that is placed on the stage. The top plate heater is provided on a top plate of the processing container that faces the stage. The control device controls temperatures of the stage heater and the top plate heater. Furthermore, the control device controls a temperature of the stage heater by a first temperature unit to thereby control a temperature of the substrate to be processed by the first temperature unit. Furthermore, the control device controls a temperature of the top plate heater by a second temperature unit to thereby control a temperature of the substrate to be processed by radiation heat radiated via the top plate by a temperature unit smaller than the first temperature unit”.

According to an aspect of embodiments, the present disclosure provides a film deposition apparatus capable of improving uniformity of thickness of an organic film formed on a substrate.

### SUMMARY

According to an aspect of the present disclosure, a film deposition apparatus includes a processing container, a stage, a heat-insulating member, a gas supply, a first heater, and a second heater. The stage is accommodated in the processing container, and on which a substrate is placed. The heat-insulating member includes a plurality of penetration holes, and is located on or above the stage to cover the substrate placed on the stage. The gas supply supplies gas of a first monomer and gas of a second monomer into the processing container to form an organic film of a polymer on the substrate by a polymerization reaction between the first monomer and the second monomer. The first heater heats a side wall of the processing container to a first temperature. The second heater heats the stage to a second temperature lower than the first temperature. In a case where the organic film of the polymer is formed on the substrate, the heat-insulating member is in contact with the stage, and is not in contact with the processing container.

### BRIEF DESCRIPTION OF DRAWINGS

FIG. 1 is a schematic cross-sectional view illustrating one example of a film deposition apparatus according to an embodiment of the present disclosure;

FIG. 2 is a diagram illustrating one example of a surface on a processing space side of a top plate;

FIG. 3 is a cross-sectional view illustrating one example of a structure of a heat-insulating member;

FIG. 4 is a plan view illustrating one example of the structure of the heat-insulating member;

FIG. 5 is a diagram illustrating one example of a position of a stage at the time of transferring a substrate;

FIG. 6 is a diagram illustrating one example of a position of the stage at the time of cleaning;

FIG. 7 is a cross-sectional view illustrating another example of the structure of the heat-insulating member;

FIG. 8 is a cross-sectional view illustrating another example of the structure of the heat-insulating member;

FIG. 9 is side view illustrating another example of the structure of the heat-insulating member;

FIG. 10 is a cross-sectional view illustrating another example of the structure of the heat-insulating member; and

FIG. 11 is a plan view illustrating another example of the structure of the heat-insulating member.

### DESCRIPTION OF EMBODIMENTS

Exemplary embodiments of a film deposition apparatus disclosed in the present application will be explained below in detail with reference to the accompanying drawings. The film deposition apparatus disclosed in the present application is not limited to the embodiments explained below.

In vapor deposition polymerization, a film deposition rate greatly varies depending on a substrate temperature. Thus, it is required to make a substrate temperature distribution more uniform so as to make a thickness of a polymer film to be deposited uniform.

Thus, the present disclosure provides a technique capable of improving uniformity of a thickness of an organic film to be formed on a substrate.

### Configuration of Film Deposition Apparatus 1

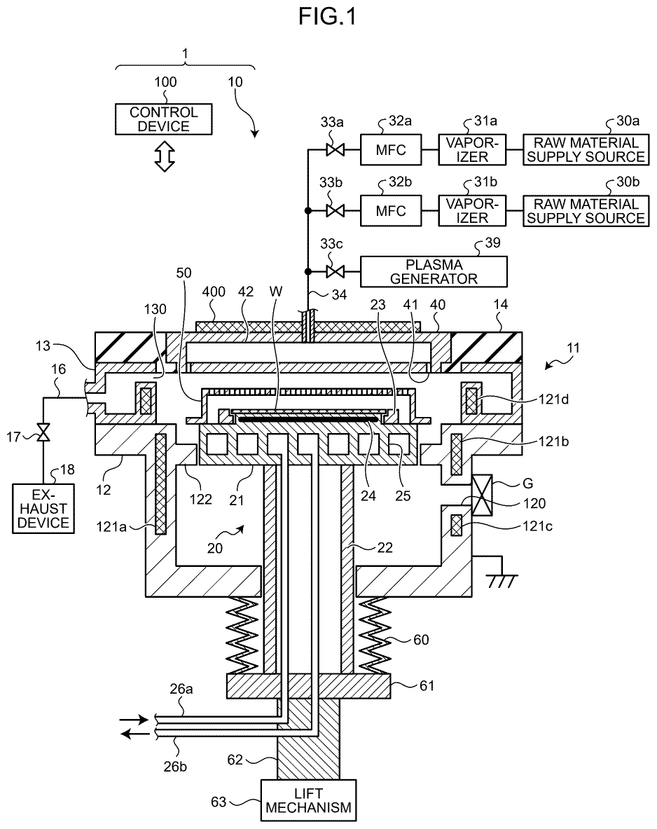

FIG. 1 is a schematic cross-sectional view illustrating one example of a film deposition apparatus 1 according to an embodiment of the present disclosure. The film deposition apparatus 1 according to the present embodiment deposits an organic polymer film on a substrate W by vapor deposition polymerization with the use of a plurality of monomers. The film deposition apparatus 1 includes an apparatus body 10 and a control device 100 that controls the apparatus body 10. The apparatus body 10 includes a processing container 11 that accommodates therein the substrate W.

The processing container 11 includes a lower container 12, which is formed of a metal such as aluminum, and an exhaust duct 13. The lower container 12 constitutes a lower portion of the processing container 11. The lower container 12 is grounded. Side wall heaters 121a to 121c are embedded in side walls of the lower container 12. The side wall heaters 121a to 121c heat the side walls of the lower container 12 to a temperature of around 150° C., for example, to inhibit a reaction by-product from adhering to the side walls of the lower container 12. The temperature of around 150° C. is one example of a first temperature. Furthermore, an opening 120 is formed in the side wall of the lower container 12, through which the substrate W is to be carried in/out. The opening 120 is opened/closed by a gate valve G.

The exhaust duct 13 is provided on top of the lower container 12, and constitutes a part of a side wall of the processing container 11. According to the present embodiment, the exhaust duct 13 has a rectangular shape with a hollow vertical cross section, and is constituted to curve in a circular manner along an upper portion of the lower container 12. In the exhaust duct 13, a slit-like exhaust port 130 is formed along a direction in which the exhaust duct 13 extends. The exhaust port 130 is located outside of an area of the substrate W along a periphery of the substrate W accommodated in the processing container 11, so as to discharge gas in the processing container 11. Furthermore, a side wall heater 121d is embedded in a side wall of the exhaust duct 13 that faces an inner space of the processing container 11. The side wall heater 121d heats the side wall of the exhaust duct 13 to a temperature of around 150° C. so as to inhibit adhesion of a reaction by-product to the side wall of the exhaust duct 13. The control device 100 controls temperatures of the side wall heaters 121a to 121d. The side wall heaters 121a to 121d are one example of first heaters.

Furthermore, one end of an exhaust pipe 16 is connected with the exhaust duct 13. The other end of the exhaust pipe 16 is connected with an exhaust device 18 having a vacuum pump or the like via a pressure regulating valve 17 such as an Auto Pressure Controller (APC) valve. The pressure regulating valve 17 is controlled by the control device 100 to control a pressure in the processing container 11 to be a predetermined level. Note that the exhaust pipe 16, the pressure regulating valve 17, and the exhaust device 18 may be heated to a temperature of around 150° C., for example, by a not-illustrated heater so as to inhibit adhesion of a reaction by-product thereon.

A support structure 20 is provided in the processing container 11, on which the substrate W is to be placed. The support structure 20 includes a stage 21 and a support part 22. The stage 21 is constituted by a metal such as aluminum, and the substrate W is placed on a top surface thereof. The support part 22 is cylindrically constituted by a metal such as aluminum to support the stage 21 from below.

A stage heater 24 is embedded in the stage 21. The stage heater 24 heats the substrate W placed on the stage 21 according to electric power supplied thereto. At the time of depositing an organic film, the substrate W is heated to a temperature suitable for vapor deposition polymerization (for example, 60° C. to 100° C.). Electric power supplied to the stage heater 24 is controlled by the control device 100. A temperature suitable for vapor deposition polymerization is one example of a second temperature.

Furthermore, a flow path 25, through which a heating medium circulates, is formed in the stage 21. A not-illustrated temperature control mechanism such as a chiller unit is connected with the flow path 25 via a pipe 26a and a pipe 26b. The heating medium adjusted to a predetermined temperature by the temperature control mechanism is supplied to the flow path 25 via the pipe 26a, and the heating medium having passed through the flow path 25 is returned to the temperature control mechanism via the pipe 26b. The heating medium circulating in the flow path 25 controls a temperature of the stage 21. The control device 100 controls temperatures of the temperature control mechanism and the heating medium.

A ring-shaped edge ring 23 is removably located on the stage 21 around the substrate W placed on an upper surface of the stage 21.

The support part 22 is located in the lower container 12 so as to pass through an opening formed on the bottom of the lower container 12. A flange 61 constituted by a conductive material is connected with a lower end of the support part 22. An upper end of a shaft 62 is connected with a lower surface of the flange 61. A lower end of the shaft 62 is connected with a lift mechanism 63. The lift mechanism 63 lifts/lowers the shaft 62. The lift mechanism 63 lifts/lowers the shaft 62, so that the support structure 20 lifts/lowers integrally with the flange 61. The lift mechanism 63 controls a distance between the substrate W placed on the stage 21 and a top plate 40 to be mentioned later.

The bottom of the lower container 12 is connected with the flange 61 via a bellows 60 that is made of a metal. This maintains airtightness of the processing container 11 even in a case where the lift mechanism 63 lifts/lowers the support structure 20. The bellows 60 and the flange 61 are grounded via the processing container 11. The stage 21 is connected with the flange 61 via the support part 22 to be grounded via the flange 61.

The top plate 40 is provided above the exhaust duct 13 in a ring shape. The top plate 40 is supported by an insulator 14 that is located on the exhaust duct 13. The insulator 14 and the top plate 40 constitute a ceiling portion of the processing container 11. In the processing container 11, a space between the substrate W placed on the stage 21 and the top plate 40 is defined as a processing space.

A diffusion chamber 42 for diffusing gas is formed in the top plate 40. A pipe 34 for supplying gas into the diffusion chamber 42 is connected with an upper surface of the top plate 40. Furthermore, a plurality of discharge ports 41 that communicate with the diffusion chamber 42 is formed on a lower surface of the top plate 40. Gas supplied into the diffusion chamber 42 from the pipe 34 diffuses in the diffusion chamber 42 to be supplied into the processing space from the discharge ports 41.

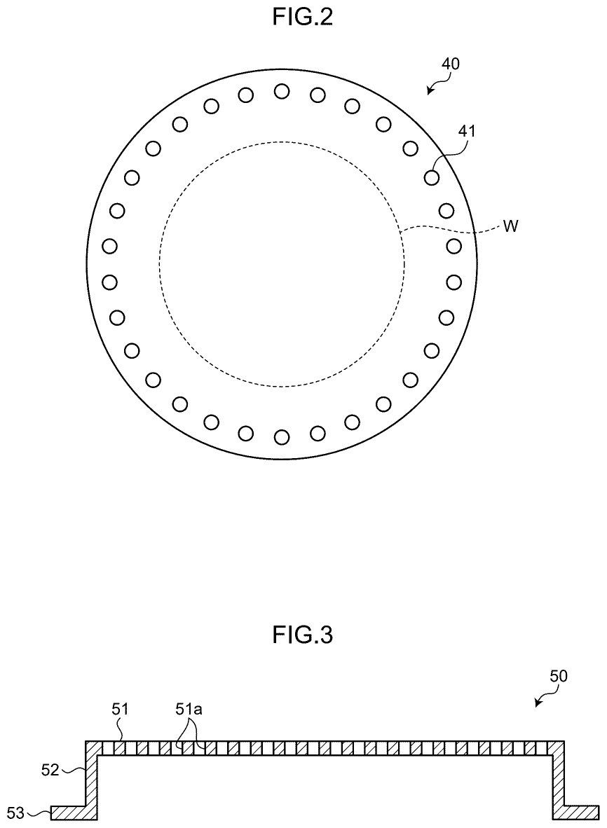

FIG. 2 is a diagram illustrating one example of a surface on the processing space side of the top plate 40. FIG. 2 illustrates an external form of the substrate W placed on the stage 21 by using a dashed line. According to the present embodiment, as illustrated in FIG. 2, for example, the plurality of discharge ports 41 are located along a periphery of the substrate W placed on the stage 21 to supply gas that has been supplied into the diffusion chamber 42 into the outside of an area of the substrate W in the processing container 11. The discharge ports 41 may be located just above the edge ring 23 as long as gas is discharge gas into the outside of the area of the substrate W. The top plate 40 is one example of a gas supply.

Back to FIG. 1, explanation will be continued. A heat-insulating member 50 is provided on or above the stage 21 outside the edge ring 23 so as to cover the substrate W that is placed on the stage 21. The heat-insulating member 50 is formed of a material having high thermal conductivity such as aluminum. A thickness of the heat-insulating member 50 is preferably 3 mm or more and 8 mm or less. Thus, it is possible to obtain balance between shielding a property and thermal conductivity.

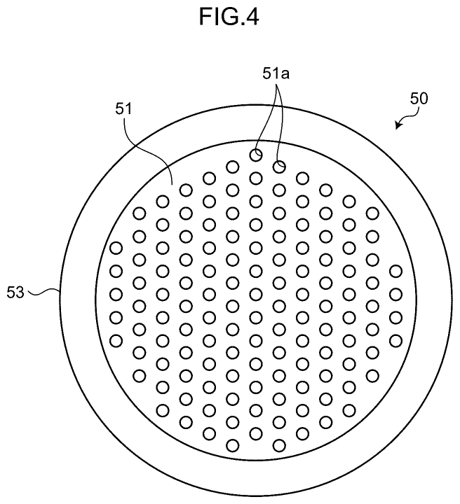

FIG. 3 is a cross-sectional view illustrating one example of a structure of the heat-insulating member 50. FIG. 4 is a plan view illustrating one example of the structure of the heat-insulating member 50. As illustrated in FIG. 3, for example, the heat-insulating member 50 includes a plate-like portion 51, a cylindrical portion 52, and a flange portion 53. As illustrated in FIG. 4, for example, the plate-like portion 51 is formed to be in substantially circular plate-shaped, and includes a plurality of penetration holes 51a that pass through the plate-like portion 51 in a thickness direction. According to the present embodiment, in the plate-like portion 51, an opening rate of the penetration holes 51a is 10% or more and 20% or less. Thus, it is possible to efficiently supply gas for depositing an organic film on the substrate W between the heat-insulating member 50 and the substrate W while covering the substrate W. The cylindrical portion 52 is cylindrically formed along an outer periphery of the plate-like portion 51. The plate-like portion 51 is provided at an upper end of the cylindrical portion 52. The flange portion 53 is in a ring shape to be provided at a lower end of the cylindrical portion 52. Furthermore, in a case where the heat-insulating member 50 is located on the stage 21, the flange portion 53 extends from the cylindrical portion 52 to the outside of the stage 21 along a surface of the stage 21 on which the substrate is placed.

In a case where an organic film is formed on the substrate W, the heat-insulating member 50 is placed on the stage 21 and is in contact with the stage 21, as illustrated in FIG. 1, for example. Meanwhile, in a case where an organic film is deposited on the substrate W, the heat-insulating member 50 is not in contact with the processing container 11.

A stepped portion 122 protruding toward the support structure 20 is provided on the side wall of the lower container 12. When viewed from above, an external form of the heat-insulating member 50 is larger than that of the stage 21. Therefore, when the support structure 20 lowers, the heat-insulating member 50 is placed on the stepped portion 122, so that the heat-insulating member 50 is separated from the stage 21.

Here, at the time of depositing an organic film, a temperature of the substrate W is controlled within a range of 60° C. to 100° C., for example. However, the side walls of the exhaust duct 13 and the lower container 12 are heated to around 150° C. by the side wall heaters 121a to 121d. Therefore, a temperature in the vicinity of an edge of the substrate W may be higher than a temperature in the vicinity of the center of the substrate W due to radiation heat from the side walls of the exhaust duct 13 and the lower container 12. This may cause a difference in thickness of a deposited organic film between the vicinity of the center and the vicinity of the edge of the substrate W.

Thus, according to the present embodiment, the substrate W is covered with the heat-insulating member 50 at the time of film deposition to thereby inhibit radiation heat from the side walls of the exhaust duct 13 and the lower container 12. Furthermore, at the time of film deposition, the heat-insulating member 50 is in contact with the stage 21, while not being in contact with the processing container 11, as illustrated in FIG. 1, for example. Therefore, the entire heat-insulating member 50 reaches a temperature equivalent to that of the stage 21. Thus, uniformity of temperature distribution of the substrate W improves, so that thickness uniformity of an organic film deposited on the substrate W can improve.

A top plate heater 400 is provided on an upper surface of the top plate 40. The top plate heater 400 heats the top plate 40 to a temperature around 150° C., for example, to thereby inhibit adhesion of a reaction by-product to the inside of the diffusion chamber 42 and to a lower surface of the top plate 40. The control device 100 controls a temperature of the top plate heater 400.

A valve 33a, a valve 33b, and a valve 33c are connected with the pipe 34. A raw material supply source 30a is connected with the valve 33a via a mass flow controller (MFC) 32a and a vaporizer 31a. A raw material supply source 30b is connected with the valve 33b via an MFC 32b and a vaporizer 31b. A plasma generator 39 is connected with the valve 33c.

The raw material supply source 30a is a supply source of a first monomer such as an isocyanate. The vaporizer 31a vaporizes liquid of the first monomer that has been supplied from the raw material supply source 30a. The MFC 32a controls a flow rate of a gas of the first monomer that has been vaporized by the vaporizer 31a. The valve 33a controls supply of the gas of the first monomer to the pipe 34 and stop thereof.

The raw material supply source 30b is a supply source of a second monomer such as an amine. The vaporizer 31b vaporizes liquid of the second monomer that has been supplied from the raw material supply source 30b. The MFC 32b controls a flow rate of gas of the second monomer that has been vaporized by the vaporizer 31b. The valve 33b controls supply of the gas of the second monomer to the pipe 34 and stop thereof.

Gas of the first monomer that has been supplied from the raw material supply source 30a and gas of the second monomer that has been supplied from the raw material supply source 30b are supplied into the diffusion chamber 42 via the pipe 34 to be mixed with each other while diffusing in the diffusion chamber 42. Then, a mixed gas of the first monomer and the second monomer is supplied into the processing container 11 via the discharge ports 41 to form an organic film of a polymer having poly-urea bonds on the substrate W that is placed on the stage 21.

The plasma generator 39 converts cleaning gas into plasma, and supplies an active species or the like contained in the plasma into the diffusion chamber 42 of the top plate 40 via the pipe 34. The active species or the like that has been supplied into the diffusion chamber 42 is supplied into the processing container 11 via the discharge ports 41. As cleaning gas, for example, oxygen gas and/or a halogen-containing gas may be used. As the halogen-containing gas, for example, chlorine gas, hydrogen chloride gas, bromine gas, hydrogen bromide gas, hydrogen iodide gas, nitrogen fluoride gas, etc. may be used.

After an organic film has been formed on the several substrates W by vapor deposition polymerization, the plasma generator 39 converts cleaning gas into plasma, and an active species or the like contained in the plasma is supplied into the diffusion chamber 42 and the processing container 11. Then, a deposition adhering to the diffusion chamber 42, the heat-insulating member 50, and the processing container 11 is removed by the active species or the like.

The control device 100 includes a memory, a processor, and an input/output interface. The processor in the control device 100 reads out and executes a program and/or a recipe stored in the memory to thereby control each unit of the apparatus body 10 via the input/output interface.

### Motion of Heat-insulating Member 50

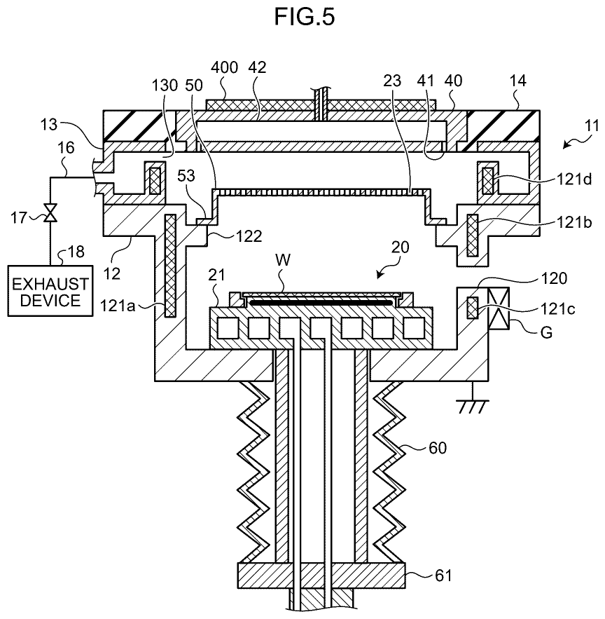

In a case where an organic film is deposited on the substrate W, the stage 21 is in a position illustrated in FIG. 1, for example, and the heat-insulating member 50 is placed on the stage 21. On the other hand, in a case where carrying-in/out of the substrate W is performed, the stage 21 lowers to a position illustrated in FIG. 5, for example. In a process where the stage 21 lowers, the flange portion 53 of the heat-insulating member 50 is placed on the stepped portion 122 of the processing container 11, so that the stage 21 is separated from the heat-insulating member 50. Thus, it is possible to perform carrying-in/out of the substrate W on the stage 21. The position of the stage 21 in the case where an organic film is deposited on the substrate W is one example of a first position, and the position of the stage 21 in the case where carrying-in/out of the substrate W is performed is one example of a second position.

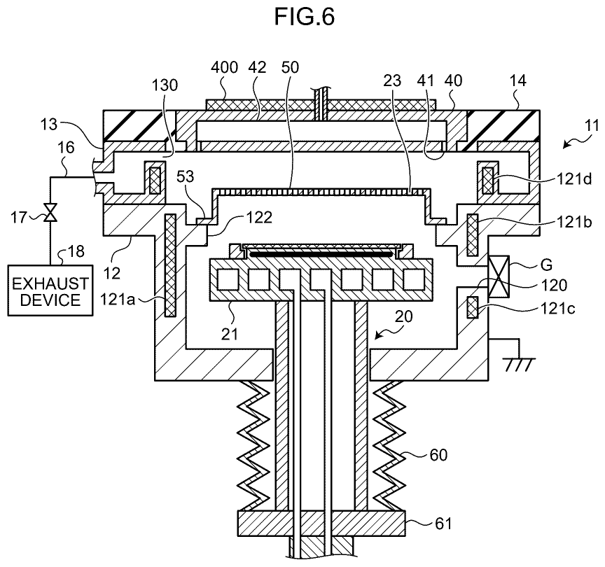

Furthermore, in a case where cleaning an inside of the processing container 11 is performed, as illustrated in FIG. 6, for example, the stage 21 lowers to a position that is lower than the position of the stage 21 in the case where an organic film is deposited on the substrate W and that is higher than the position of the stage 21 in the case where carrying-in/out of the substrate W is performed. The position of the stage 21 in the case where cleaning the inside of the processing container 11 is performed is one example of a third position. Thus, in the case where cleaning the inside of the processing container 11 is performed, the heat-insulating member 50 is in contact with the stepped portion 122, so that the heat-insulating member 50 is heated to a temperature equivalent to that of the side wall of the processing container 11 via the stepped portion 122. Thus, it is possible to efficiently remove the reaction by-product adhering to the heat-insulating member 50.

Note that in the case where cleaning the inside of the processing container 11 is performed, the stage 21 is set at a position higher than that of the stage 21 in the case where carrying-in/out of the substrate W is performed. Thus, a distance between the top plate 40 and the stage 21 is shorter compared with a case where carrying-in/out of the substrate W is performed, thus enabling an active species supplied from the top plate 40 to efficiently reach a surface of the stage 21. Thus, it is possible to efficiently remove a reaction by-product adhering to an upper surface of the stage 21 and the edge ring 23.

The embodiment has been explained so far. As described above, the film deposition apparatus according to the embodiment includes a processing container (processing container 11), a stage (stage 21), a heat-insulating member (heat-insulating member 50), a gas supply (top plate 40), first heaters (side wall heaters 121a to 121d), and a second heater (stage heater 24). The stage is accommodated in the processing container, and a substrate (substrate W) is placed thereon. The heat-insulating member includes a plurality of penetration holes (penetration holes 51a), and is located on or above the stage so as to cover the substrate that is placed on the stage. The gas supply supplies gas of a first monomer and gas of a second monomer into the processing container to form an organic film of a polymer on the substrate by a polymerization reaction between the first monomer and the second monomer. The first heaters heat a side wall of the processing container to a first temperature. The second heater heats the stage to a second temperature that is lower than the first temperature. In a case where an organic film of the polymer is formed on the substrate, the heat-insulating member is in contact with the stage, while not being in contact with the processing container. Thus, it is possible to improve uniformity of a thickness of the organic film to be formed on the substrate W.

Furthermore, according to the above-mentioned embodiment, the heat-insulating member includes the plate-like portion (plate-like portion 51) that has the plurality of penetration holes formed therein and that is located in a position facing the substrate and the cylindrical portion (cylindrical portion 52) that is located between the plate-like portion and the stage. Thus, it is possible to easily form the heat-insulating member 50.

Furthermore, according to the above-mentioned embodiment, an opening rate of the penetration holes is 10% or more and 20% or less in the plate-like portion. Thus, it is possible to efficiently supply gas for depositing an organic film on the substrate W between the heat-insulating member 50 and the substrate W while covering the substrate W.

Furthermore, the film deposition apparatus according to the above-mentioned embodiment further includes a lift mechanism (lift mechanism 63) that lifts/lowers the stage. Furthermore, the heat-insulating member includes a flange portion (flange portion 53) that extends from a cylindrical portion to the outside of the stage along a surface of the stage on which the substrate is placed. The processing container includes a stepped portion (stepped portion 122) that is provided on an inner side wall thereof. The lift mechanism lowers the stage at the time of carrying-in/out the substrate, and places the flange portion of the heat-insulating member on the stepped portion to thereby separate the heat-insulating member from the stage. Thus, it is possible to perform carrying-in/out of the substrate W.

Furthermore, according to the above-mentioned embodiment, the flange portion is provided at a lower end of the cylindrical portion. Thus, it is possible to place the heat-insulating member 50 on the stepped portion 122 with a short moving distance of the stage 21 in a vertical direction.

Furthermore, according to the above-mentioned embodiment, the lift mechanism lowers the stage in performing cleaning on an inside of the processing container, and places the flange portion of the heat-insulating member on the stepped portion to thereby heat the heat-insulating member to a first temperature via the stepped portion. Thus, it is possible to efficiently remove a reaction by-product adhering to the heat-insulating member 50.

Furthermore, according to the above-mentioned embodiment, the lift mechanism controls a position of the stage such that a level of the stage in performing cleaning on the inside of the processing container is a third position that is lower than a first position in processing the substrate, and that is higher than a second position in performing carrying-in/out of the substrate. Thus, it is possible to efficiently remove a reaction by-product adhering to an upper surface of the stage 21.

Furthermore, according to the above-mentioned embodiment, the heat-insulating member is formed of aluminum. Thus, it is possible to keep a temperature of the entire heat-insulating member 50 more uniform, thus making it possible to improve uniformity of temperature distribution of the substrate W.

Furthermore, according to the above-mentioned embodiment, a thickness of the heat-insulating member is 3 mm or more and 8 mm or less. Thus, it is possible to obtain balance between a shielding property and thermal conductivity.

### Others

Note that the technique disclosed in the present application is not limited to the above-mentioned embodiment, and various modifications can be made to the above-described one within the spirit of the invention.

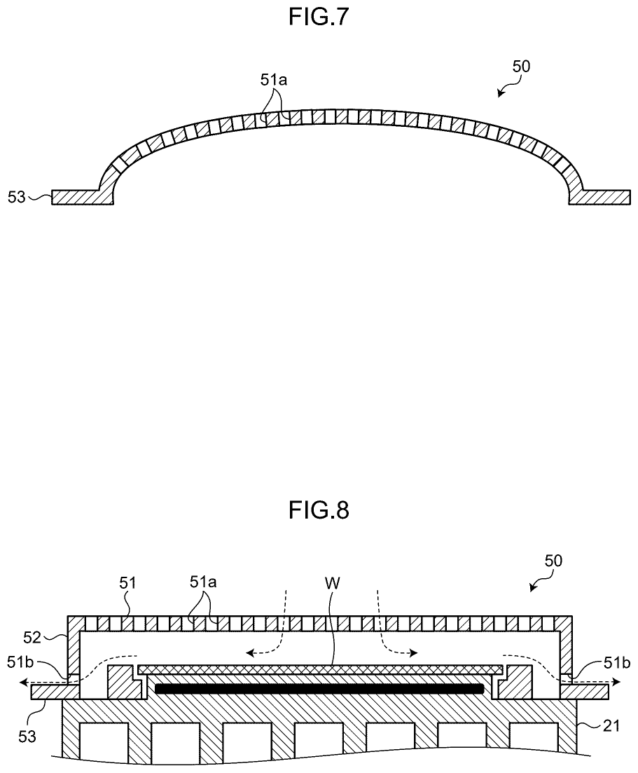

For example, according to the above-mentioned embodiment, the heat-insulating member 50 is structured to include the plate-like portion 51 and the cylindrical portion 52; however, the disclosed technique is not limited thereto. As another embodiment, as illustrated in FIG. 7, for example, the heat-insulating member 50 may be dome-shaped to include the flange portion 53 and the plurality of penetration holes 51a.

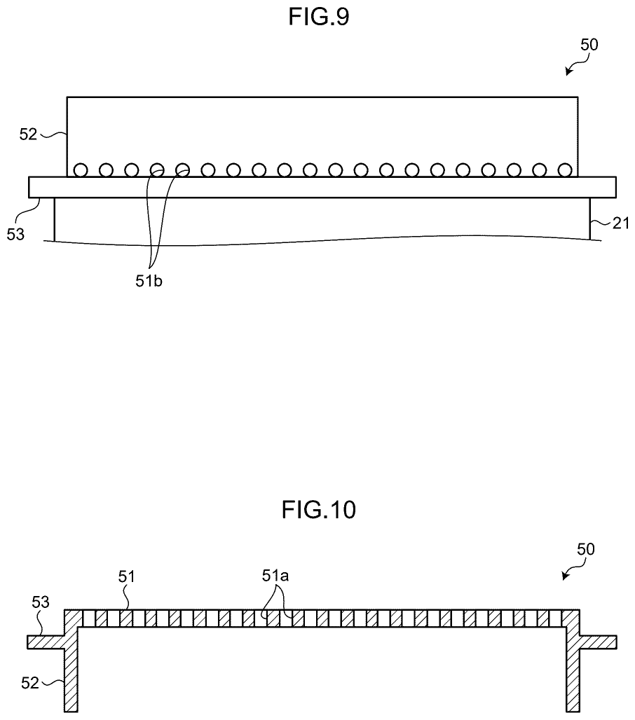

Furthermore, in the heat-insulating member 50 according to the above-mentioned embodiment, the plurality of penetration holes 51a is formed only in the plate-like portion 51; however, the disclosed technique is not limited thereto. As another embodiment, as illustrated in FIG. 8 and FIG. 9, for example, a plurality of penetration holes 51b may be formed also in the cylindrical portion 52 in a thickness direction of the cylindrical portion 52. In this instance, the plurality of penetration holes 51b may be preferably formed in a position closer to a lower end than to an upper end of the cylindrical portion 52. Thus, as illustrated by a dotted arrow in FIG. 8, for example, a gas flow is generated, which flows in from the penetration holes 51a of the plate-like portion 51 and further passes through a space between the plate-like portion 51 and the substrate W to reach the penetration holes 51b. Thus, it is possible to inhibit retention of gas in the heat-insulating member 50.

Furthermore, in the heat-insulating member 50 according to the above-mentioned embodiment, the flange portion 53 is provided at the lower end of the cylindrical portion 52; however, the disclosed technique is not limited thereto. As another embodiment, as illustrated in FIG. 10, for example, the flange portion 53 may be provided between the upper end and the lower end of the cylindrical portion 52. Note that the flange portion 53 may be provided at the upper end of the cylindrical portion 52.

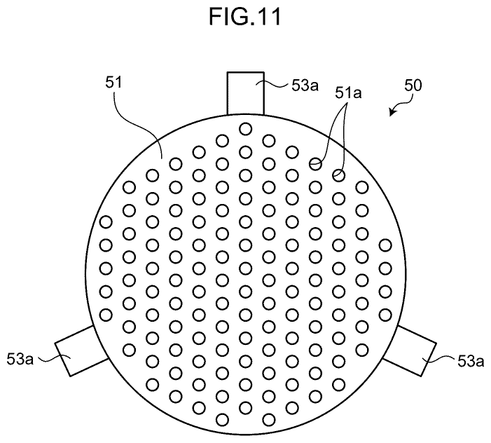

Furthermore, as illustrated in FIG. 4, for example, in the heat-insulating member 50 according to the above-mentioned embodiment, the flange portion 53 in a ring shape is provided at the lower end of the cylindrical portion 52; however, the disclosed technique is not limited thereto. For the purpose of placing the heat-insulating member 50 on the stepped portion 122 of the lower container 12 when the stage 21 lowers, the plurality of protruding portions 53a may be provided at the lower end of the cylindrical portion 52 in place of the flange portion 53 in a ring shape, as another embodiment, as illustrated in FIG. 11, for example. Note that the stepped portion 122 in the processing container 11 is in contact with the protruding portions 53a, so that heat of the stepped portion 122 of the lower container 12 is transmitted to the heat-insulating member 50 via the protruding portions 53a. For that reason, depending on thermal conductivities of the heat-insulating member 50 and the protruding portions 53a, unevenness of temperature distribution may occur in the heat-insulating member 50. In this case, the number of the protruding portions 53a (three in example of FIG. 11) may be increased. Thus, it is possible to reduce the unevenness of the temperature distribution in the heat-insulating member 50.

Furthermore, according to the above-mentioned embodiment, an isocyanate is used as the first monomer, and an amine is used as the second monomer so as to form a polymer film having urea bonds (—NH—CO—NH—) on a surface of the substrate W; however, the disclosed technique is not limited thereto. For example, an epoxide may be used as the first monomer, and an amine may be used as the second monomer so as to form a polymer film having 2-ethanolamine bonds (—NH—CH2—CH(OH)—) on a surface of the substrate W. Alternatively, an isocyanate may be used as the first monomer, and alcohol may be used as the second monomer so as to form a polymer film having urethane bonds (—NH—CO—O—) on a surface of the substrate W. Alternatively, an acyl halide may be used as the first monomer, and an amine may be used as the second monomer so as to form a polymer film having amide bonds (—NH—CO—) on a surface of the substrate W. Alternatively, carboxylic acid anhydride may be used as the first monomer, and an amine may be used as the second monomer so as to form a polymer film having imide bonds (—CO—N(—)—CO—) on a surface of the substrate W.

According to various aspects and embodiments, it is possible to improve uniformity of a thickness of an organic film formed on a substrate.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

Furthermore, regarding the above-mentioned embodiment, the following Supplementary Notes are disclosed.

### (Supplementary Note 1)

A film deposition apparatus including:
a processing container;
a stage that is accommodated in the processing container, and on which a substrate is placed;
a heat-insulating member that includes a plurality of penetration holes, and that is located on or above the stage to cover the substrate placed on the stage;
a gas supply that supplies gas of a first monomer and gas of a second monomer into the processing container to form an organic film of a polymer on the substrate by a polymerization reaction between the first monomer and the second monomer;
a first heater that heats a side wall of the processing container to a first temperature; and
a second heater that heats the stage to a second temperature lower than the first temperature, wherein
in a case where the organic film of the polymer is formed on the substrate, the heat-insulating member is in contact with the stage, and is not in contact with the processing container.

### (Supplementary Note 2)

The film deposition apparatus according to Supplementary Note 1, wherein
the heat-insulating member includes:
   a plate-like portion that has a plurality of penetration holes formed therein, and that is located in a position facing the substrate; and
   a cylindrical portion that is located between the plate-like portion and the stage.

### (Supplementary Note 3)

The film deposition apparatus according to Supplementary Note 2, wherein
an opening rate of the penetration holes in the plate-like portion is 10% or more and 20% or less in the plate-like portion.

### (Supplementary Note 4)

The film deposition apparatus according to Supplementary Note 2 or 3, wherein
the cylindrical portion includes a plurality of penetration holes.

### (Supplementary Note 5)

The film deposition apparatus according to Supplementary Note 4, wherein
the plurality of penetration holes included in the cylindrical portion is formed in a position closer to a lower end than to an upper end of the cylindrical portion.

### (Supplementary Note 6)

The film deposition apparatus according to any one of Supplementary Notes 2 to 5, further including:
a lift mechanism that lifts/lowers the stage, wherein
the heat-insulating member includes a flange portion that extends from the cylindrical portion to an outside of the stage along a surface of the stage on which the substrate is placed,
the processing container includes a stepped portion provided on an inner side wall, and
the lift mechanism lowers the stage at a time of carrying-in/out the substrate, and places the flange portion of the heat-insulating member on the stepped portion to separate the heat-insulating member from the stage.

### (Supplementary Note 7)

The film deposition apparatus according to Supplementary Note 6, wherein
the flange portion is provided at a lower end of the cylindrical portion.

### (Supplementary Note 8)

The film deposition apparatus according to Supplementary Note 6 or 7, wherein
the lift mechanism lowers the stage in performing cleaning on an inside of the processing container, and places the flange portion of the heat-insulating member on the stepped portion to heat the heat-insulating member to the first temperature via the stepped portion.

### (Supplementary Note 9)

The film deposition apparatus according to Supplementary Note 8, wherein
the lift mechanism controls a position of the stage such that a level of the stage in performing cleaning on the inside of the processing container is a third position that is lower than a first position in processing the substrate, and that is higher than a second position in performing carrying-in/out of the substrate.

### (Supplementary Note 10)

The film deposition apparatus according to any one of Supplementary Notes 1 to 9, wherein
the heat-insulating member is formed of aluminum.

### (Supplementary Note 11)

The film deposition apparatus according to any one of Supplementary Notes 1 to 10, wherein
a thickness of the heat-insulating member is 3 mm or more and 5 mm or less.

What is claimed is:

1. A film deposition apparatus comprising:
a processing container;
a stage that is accommodated in the processing container, and on which a substrate is placed;
a heat-insulating member that includes a plurality of penetration holes, and that is located on or above the stage to cover the substrate placed on the stage;
a gas supply that supplies gas of a first monomer and gas of a second monomer into the processing container to form an organic film of a polymer on the substrate by a polymerization reaction between the first monomer and the second monomer;
a first heater that heats a side wall of the processing container to a first temperature; and
a second heater that heats the stage to a second temperature lower than the first temperature, wherein
in a case where the organic film of the polymer is formed on the substrate, the heat-insulating member is in contact with the stage, and is not in contact with the processing container.

2. The film deposition apparatus according to claim 1, wherein
the heat-insulating member includes:
a plate-like portion that has a plurality of penetration holes formed therein, and that is located in a position facing the substrate; and
a cylindrical portion that is located between the plate-like portion and the stage.

3. The film deposition apparatus according to claim 2, wherein
an opening rate of the penetration holes in the plate-like portion is 10% or more and 20% or less in the plate-like portion.

4. The film deposition apparatus according to claim 2, wherein
the cylindrical portion includes a plurality of penetration holes.

5. The film deposition apparatus according to claim 4, wherein
the plurality of penetration holes included in the cylindrical portion is formed in a position closer to a lower end than to an upper end of the cylindrical portion.

6. The film deposition apparatus according to claim 2, further comprising:
a lift mechanism that lifts/lowers the stage, wherein
the heat-insulating member includes a flange portion that extends from the cylindrical portion to an outside of the stage along a surface of the stage on which the substrate is placed,
the processing container includes a stepped portion provided on an inner side wall, and
the lift mechanism lowers the stage at a time of carrying-in/out the substrate, and places the flange portion of the heat-insulating member on the stepped portion to separate the heat-insulating member from the stage.

7. The film deposition apparatus according to claim 6, wherein
the flange portion is provided at a lower end of the cylindrical portion.

8. The film deposition apparatus according to claim 6, wherein
the lift mechanism lowers the stage in performing cleaning on an inside of the processing container, and places the flange portion of the heat-insulating member on the stepped portion to heat the heat-insulating member to the first temperature via the stepped portion.

9. The film deposition apparatus according to claim 8, wherein
the lift mechanism controls a position of the stage such that a level of the stage in performing cleaning on the inside of the processing container is a third position that is lower than a first position in processing the substrate, and that is higher than a second position in performing carrying-in/out of the substrate.

10. The film deposition apparatus according to claim 1, wherein
the heat-insulating member is formed of aluminum.

11. The film deposition apparatus according to claim 1, wherein
a thickness of the heat-insulating member is 3 mm or more and 5 mm or less.
